(19) United States
(12) Patent Application Publication
(10) Pub. No.: US 2026/0313951 A1
(43) Pub. Date: Oct. 8, 2026

(54) LDMOS TRANSISTOR DESIGN FOR PROVIDING IMMUNITY TO CONE DEFECTS

(71) Applicant: Microchip Technology Inc., Chandler, AZ (US)

(72) Inventors: Robin Liu, Fremont, CA (US); Pascal Rohr, Saint Savournin (FR); Ziyan Xu, San Jose, CA (US); Gilles Mantout, Rousset (FR); Carmen Ong, San Francisco, CA (US)

(73) Assignee: Microchip Technology Inc., Chandler, AZ (US)

(21) Appl. No.: 19/187,045

(22) Filed: Apr. 23, 2025

Related U.S. Application Data
(60) Provisional application No. 63/783,625, filed on Apr. 4, 2025.

(51) Int. Cl. H10D 30/65; H10D 30/01; H10D 62/10; H10D 64/00; H10D 64/27

(52) U.S. Cl. CPC H10D 30/65; H10D 30/0281; H10D 62/116; H10D 64/111; H10D 64/529

(57) ABSTRACT

A laterally diffused metal-oxide-semiconductor (LDMOS) transistor that provides immunity from shallow trench isolation (STI) cone defects is disclosed. The LDMOS may include a doped body and a high voltage well formed in a substrate, a gate electrode above the doped body, an STI region, including a dielectric material, within the high voltage well, a cap layer covering a portion of the STI region, a poly gate spanning from the gate electrode to the high voltage well, and a field plate covering a portion of the cap layer and a metal shield spanning the field plate and the poly gate and electrically coupling the high voltage well to the doped body. The STI region may be spaced apart from an edge of the high voltage well by a first distance. An edge of the cap layer may be located a second distance from an edge of the STI region.

### RELATED PATENT APPLICATION

This application claims priority to commonly owned United States Provisional Patent Application No. 63/783,625 filed Apr. 4, 2025, the entire contents of which are hereby incorporated by reference for all purposes.

### TECHNICAL FIELD

The present disclosure relates to the design of a laterally diffused metal-oxide-semiconductor (LDMOS) transistor, and in particular to a design for an LDMOS transistor that provides immunity from shallow trench isolation (STI) cone defects.

### BACKGROUND

Shallow trench isolation (STI) regions are formed by thermally oxidizing a silicon substrate to form a silicon oxide layer on the surface of the silicon substrate. A silicon nitride layer is then deposited on top of the silicon oxide layer by chemical vapor deposition (CVD). The silicon nitride layer is patterned and used as a mask for etching a trench into the silicon substrate. However, small particles inherently present on the surface of the silicon layer, nitride layer, resist layer or substrate can block the etching process and cause defects.

One common type of defect is a cone defect, where a particle blocks the etching process, which then produces a cone shaped defect underneath the blocked area within the STI region. A cone defect may cause unwanted electrical breakdown between the silicon substrate and an active region above the STI region. This may occur because the distance between the top of the cone defect and the active region is greatly reduced compared to the intended isolation distance given by the depth of the STI region.

### SUMMARY OF THE INVENTION

Aspects provide systems and methods for a laterally diffused metal-oxide-semiconductor (LDMOS) transistor that provides immunity from shallow trench isolation (STI) cone defects. Examples of the present disclosure may include a laterally-diffused metal-oxide semiconductor (LDMOS) transistor. The LDMOS transistor may include a doped body region formed in a substrate including a source electrode. The LDMOS transistor may also include a gate electrode above the doped body region. The LDMOS transistor may additionally include a high voltage well region formed in the substrate. The LDMOS transistor may include a shallow trench isolation (STI) region within the high voltage well region. The STI region may be spaced apart from an edge of the high voltage well region by a first distance. The LDMOS transistor may also include a dielectric material within the STI region. The LDMOS transistor may include a cap layer covering a portion of the STI region. An edge of the cap layer may be located a second distance from an edge of the STI region. The LDMOS transistor may additionally include a poly gate spanning from the gate electrode to the high voltage well region. The poly gate may extend past the high voltage well region by less than the first distance. The LDMOS transistor may include a field plate covering a portion of the cap layer. The LDMOS transistor may further include a metal shield spanning the field plate and the poly gate and electrically coupling the high voltage well region to the doped body region.

In combination with any of the above examples, the doped body region may include a source electrode. The metal shield may be electrically coupled to the source electrode.

In combination with any of the above examples, the metal shield may be electrically coupled to the gate electrode.

In combination with any of the above examples, the doped body region may be in contact with the high voltage well region.

In combination with any of the above examples, a length of the field plate may be selected based on a device characteristic.

In combination with any of the above examples, a third distance from the edge of the STI region and an edge of the field plate may be selected based on a device characteristic.

In combination with any of the above examples, a length of the field plate may be less than a length of the cap layer.

Alone or in combination with any of the above examples, examples of the present disclosure may include a method of creating a laterally-diffused metal-oxide semiconductor (LDMOS) transistor. The method may include forming a doped body region in a substrate. The method may also include creating a gate electrode above the doped body region. The method may additionally include forming a high voltage well region in the substrate. The method may include etching a shallow trench isolation (STI) region within the high voltage well region. The STI region may be spaced apart from an edge of the high voltage well region by a first distance. The method may also include placing a dielectric material within the STI region. The method may additionally include covering a portion of the STI region with a cap layer. An edge of the cap layer may be located a second distance from an edge of the STI region. The method may include placing a poly gate spanning from the gate electrode to the high voltage well region and extending past the high voltage well region by less than the first distance. The method may also include covering a portion of the cap layer with a field plate. The method may further include spanning the field plate and the poly gate with a metal shield. The metal shield may electrically couple the high voltage well region to the doped body region.

In combination with any of the above examples, the method may include electrically coupling the metal shield to a source electrode in the doped body region.

In combination with any of the above examples, the method may include electrically coupling the metal shield to the gate electrode.

In combination with any of the above examples, the doped body region may be in contact with the high voltage well region.

In combination with any of the above examples, the method may include selecting a length of the field plate based on a device characteristic.

In combination with any of the above examples, the method may include selecting a third distance from the edge of the STI region and an edge of the field plate based on a device characteristic.

In combination with any of the above examples, a length of the field plate may be less than a length of the cap layer.

Alone or in combination with any of the above examples, examples of the present disclosure may include a laterally-diffused metal-oxide semiconductor (LDMOS) transistor made by a process. The process may include forming a doped body region in a substrate. The process may also include creating a gate electrode above the doped body region. The process may additionally include forming a high voltage well region in the substrate. The process may include etching a shallow trench isolation (STI) region within the high voltage well region. The STI region may be spaced apart from an edge of the high voltage well region by a first distance. The process may also include placing a dielectric material within the STI region. The process may additionally include covering a portion of the STI region with a cap layer. An edge of the cap layer may be located a second distance from an edge of the STI region. The process may include placing a poly gate spanning from the gate electrode to the high voltage well region and extending past the high voltage well region by less than the first distance. The process may also include covering a portion of the cap layer with a field plate. The process may further include spanning the field plate and the poly gate with a metal shield, the metal shield electrically coupling the high voltage well region to the doped body region.

In combination with any of the above examples, the process may include electrically coupling the metal shield to a source electrode in the doped body region.

In combination with any of the above examples, the process may include comprising electrically coupling the metal shield to the gate electrode.

In combination with any of the above examples, the doped body region may be in contact with the high voltage well region.

In combination with any of the above examples, the process may include selecting a length of the field plate based on a device characteristic.

In combination with any of the above examples, the process may include selecting a third distance from the edge of the STI region and an edge of the field plate based on a device characteristic.

### BRIEF DESCRIPTION OF THE DRAWINGS

The figures illustrate examples of systems and methods for a laterally diffused metal-oxide-semiconductor (LDMOS) transistor that provides immunity from shallow trench isolation (STI) cone defects.

FIG. 1 illustrates a cross-sectional view of an LDMOS transistor including a field plate to provides immunity from STI cone defects, according to examples of the present disclosure;

FIG. 2 illustrates a method for creating a laterally diffused metal-oxide-semiconductor (LDMOS) transistor that provides immunity from shallow trench isolation (STI) cone defects, according to examples of the present disclosure; and

FIG. 3 illustrates a more detailed version of the method shown in FIG. 2 for creating a laterally diffused metal-oxide-semiconductor (LDMOS) transistor that provides immunity from shallow trench isolation (STI) cone defects, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a laterally diffused metal-oxide-semiconductor (LDMOS) transistor that provides immunity from shallow trench isolation (STI) cone defects is provided. For some LDMOS transistors, such as high voltage LDMOS transistors using STI oxide in the drift area, cone defects in the STI region may be a concern and result in lower breakdown voltage, reduced reliability and field return. Because cone defects cannot be eliminated, methods for reducing the impact of cone defects on device performance are important for products involving high reliability and low field failure parts per million, such as, but not limited to, automotive applications. The disclosed LDMOS transistor reduces the impacts of cone defects by using a separate field plate on top of the cap layer of the LDMOS transistor to avoid contact between a cone defect and the poly gate of the LDMOS transistor, achieving immunity from cone defects in the STI region of the LDMOS transistor.

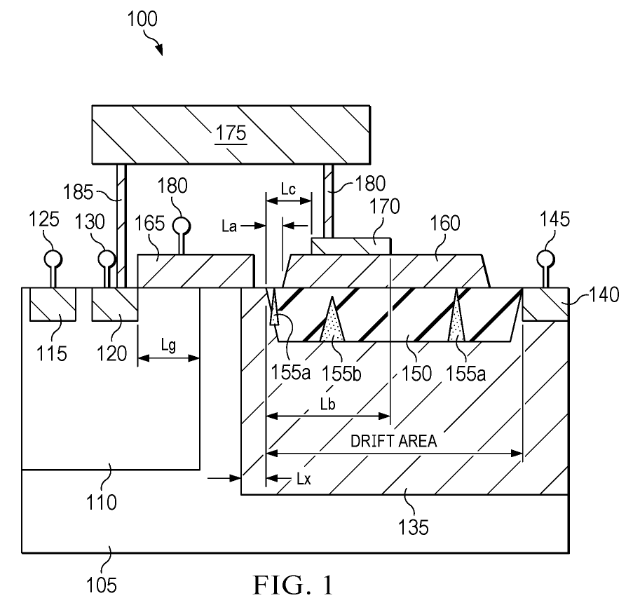

FIG. 1 illustrates a cross-sectional view of an LDMOS transistor including a field plate to provides immunity from STI cone defects, according to examples of the present disclosure. LDMOS transistor 100 may include semiconductor substrate 105 formed on a wafer surface. Semiconductor substrate 105 may be any suitable substrate, such as, but not limited to, a silicon (Si) substrate, a silicon substrate with Epi, a silicon substrate with a buried layer, or a silicon on insulator (SOI) wafer. In some examples, semiconductor substrate 105 may include a deep well below doped body region 110 and high voltage well 135.

LDMOS transistor 100 may include doped body region 110 within semiconductor substrate 105. Doped body region 110 may be a p-doped p-body or an n-doped n-body, depending on whether LDMOS transistor 100 is an N-type LDMOS transistor or a P-type LDMOS transistor. Doped body region 110 may include p+ region 115 and n+ region 120. P+ region 115 may include a contact for body electrode 125 and n+ region 120 may include a contact for source electrode 130.

Doped body region 110 may extend laterally from n+ region 120. The distance doped body region 110 extends laterally from n+ region 120 (labeled Lg in FIG. 1) may range from approximately 0.1 micrometers (μm) to approximately 1.0 μm, including from approximately 0.2 μm to approximately 0.8 μm, and more specifically approximately 0.6 μm.

LDMOS transistor 100 may also include high voltage well 135 which may form the drain region for LDMOS transistor 100. High voltage well 135 may be an nwell for an n-type LDMOS transistor or a pwell form a p-type LDMOS transistor. High voltage well 135 may include n+ region 140 which may include a contact for drain electrode 145. In some examples, high voltage well 135 may be separated from doped body region 110. In other examples, high voltage well 135 may contact doped body region 110.

High voltage well 135 may include STI region 150. STI region 150 may be formed by etching a shallow trench in high voltage well 135 and filling the trench with a dielectric, such as silicon dioxide, silicon oxy-nitride, silicon carbonitride, or any other suitable dielectric material. When the shallow trench is etched in high voltage well 135, small particles present on the surface of the substrate may block the etching process and cause cone defects 155. The lateral span of STI region 150 may be referred to as the drift area.

To prevent cone defects 155 from causing unwanted electrical breakdown between semiconductor substrate 105 and an active region above STI region 150, cap layer 160 may be deposited on STI region 150. Cap layer 160 may cover a portion of STI region 150. However, cap layer 160 may be spaced laterally from an edge of STI region 150 by a distance (labeled La in FIG. 1) to avoid cap layer 160 impacting device characteristics such as threshold voltage, on resistance, or saturation current. Cap layer 160 may be formed of any suitable material, such as, but not limited to, tetraethoxysilane (TEOS), TEOS/silicon nitride (SiN), or SiN/TEOS. Cap layer 160 may reduce the effects of cone defects 155a and 155b. However, because cap layer 160 cannot cover the entirety of STI region 150, cap layer 160 may not provide any protection from cone defects located in the portion of STI region 150 not covered by cap layer 160 (labeled La in FIG. 1), such as cone defect 155c. Because the edges of STI region 150 may be sloped, when a cone defect is present in a sloped portion of STI region 150, the cone defect may more easily extend past the top of STI region 150.

To reduce the impact of cone defects in the portion of STI region 150 not covered by cap layer 160 (labeled La in FIG. 1), LDMOS transistor 100 may decouple poly gate 165 from cap layer 160 through the addition of field plate 170 on cap layer 160. In a traditional LDMOS transistor, a poly gate may extend from a doped body region to a cap layer, overlapping both the doped body region and the cap layer. However, in LDMOS transistor 100, poly gate 165 may not extend to an edge of STI region 150 or overlap any portion of STI region 150 (e.g., the portion labeled La in FIG. 1) and therefore any cone defect in the portion of STI region 150 not covered by cap layer 160, such as cone defect 155c, may not reach poly gate 165. Poly gate 165 may be used for channel control and field plate 170 may be used for breakdown voltage optimization. Field plate 170 may be formed of any suitable conductive material, such as a polysilicon (e.g., the same type of polysilicon used for poly gate 165 or a different type of polysilicon), a metal gate, a thin film resistor, or a metal. Poly gate 165 may be coupled to gate electrode 180. Gate electrode 180 may control the flow of current through LDMOS transistor 100.

Field plate 170 may extend laterally into STI region 150 by a distance (labeled Lb in FIG. 1). An edge of field plate 170 may be laterally spaced away from an edge of STI region 150 by a distance (labeled Lc. in FIG. 1). The distance field plate 170 extends into STI region 150 and the distance an edge of field plate 170 is spaced away from an edge of STI region 150 may be selected for certain device characteristics, such as, but not limited to, a certain breakdown voltage.

To electrically couple doped body region 110 to high voltage well 135, interconnect layer 175 may bridge gate electrode 180 on field plate 170 and contact 185 coupled to doped body region 110. Interconnect layer 175 may provide a flexible connection with between doped body region 110 and field plate 170. For example, in some examples, interconnect layer 175 may couple field plate 170 with source electrode 130 and in other examples, interconnect layer 175 may couple field plate 170 with body electrode 125. In other examples, interconnect layer 175 may couple field plate 170 with any voltage supply, based on availability and application, between source voltage and drain voltage. Interconnect layer 175 may provide a physical cover for the area of LDMOS transistor 100 between poly gate 165 and field plate 170 to shield the area from other metal buses having different potential crossing and charges. For example, interconnect layer 175 may cover the exposed area between poly gate 165 and field plate 170.

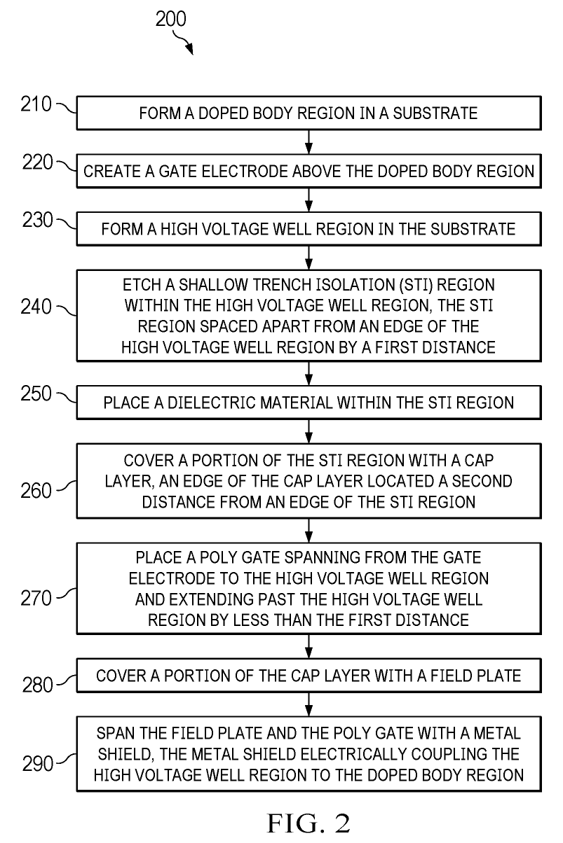

FIG. 2 illustrates a method for creating a laterally diffused metal-oxide-semiconductor (LDMOS) transistor that provides immunity from shallow trench isolation (STI) cone defects, according to examples of the present disclosure. Method 200 may be implemented using any suitable semiconductor manufacturing device designed to perform the functions disclosed herein or any other system operable to implement method 200. Although examples have been described above, other variations and examples may be made from this disclosure without departing from the spirit and scope of these disclosed examples.

Method 200 may begin at block 210 where a doped body region may be formed in a substrate. The substrate may be any suitable substrate, such as, but not limited to, a silicon (Si) substrate, a silicon substrate with Epi, a silicon substrate with a buried layer, or a silicon on insulator (SOI) wafer. In some examples, the substrate may include a deep well. The doped body region may be a p-doped p-body or an n-doped n-body, depending on whether the LDMOS transistor created using method 200 is an N-type LDMOS transistor or a P-type LDMOS transistor.

At block 220, a gate electrode may be created above the doped body region. The gate electrode may control the flow of current through the LDMOS transistor created using method 200.

At block 230, a high voltage well region may be formed in the substrate. The high voltage well may form the drain region for the LDMOS transistor created using method 200. The high voltage well may be an nwell for an n-type LDMOS transistor or a pwell form a p-type LDMOS transistor. In some examples, the high voltage well may be separated from the doped body region formed in the substrate (at block 210). In other examples, the high voltage well may contact the doped body region.

At block 240, a shallow trench isolation (STI) region may be etched within the high voltage region. The STI region may be spaced apart from an edge of the high voltage well region by a first distance. For example, the first distance may be the distance labeled Lx in FIG. 1. When the shallow trench is etched in the high voltage well, small particles present on the surface of the substrate may block the etching process and cause one or more cone defects. The lateral span of the STI region may be referred to as the drift area.

At block 250, a dielectric material may be placed in the STI region. The dielectric material may be deposited in the STI region to electrically isolate active regions of the LDMOS transistor created using method 200. The dielectric material may be any suitable dielectric material, such as but not limited to, silicon dioxide, silicon oxy-nitride, or silicon carbonitride.

At block 260, a portion of the STI region may be covered with a cap layer. The cap layer may be deposited on the STI region, but not cover the entire STI region. An edge of the cap layer may be located from an edge of the STI region by a second distance. For example, the cap layer may be spaced laterally from an edge of the STI region by the distance labeled La in FIG. 1. The cap layer may be formed of any suitable material, such as, but not limited to, tetraethoxysilane (TEOS), TEOS/silicon nitride (SiN), or SiN/TEOS. The cap layer may reduce the effects of any cone defects present in the STI region. However, because the cap layer cannot cover the entirety the STI region, the cap layer may not provide any protection from cone defects in the portion of the STI region not covered by the cap layer (the distance labeled La in FIG. 1).

At block 270, a poly gate may be placed above the substrate. The poly gate may span from the gate electrode to the high voltage well region. The poly gate may extend past an edge of the high voltage well region by less than the first distance such that the poly gate does not extend past an edge of the STI region or overlap the STI region.

At block 280, a portion of the cap layer may be covered with a field plate. The field plate (e.g., field plate 170 shown in FIG. 1) may extend laterally across the STI region by a distance. The field plate may be laterally spaced from an edge of the STI region by a distance less than the width of the cap layer.

At block 290, the field plate and the poly gate may be spanned by a metal shield (e.g., interconnect layer 175 shown in FIG. 1). The metal shield may be electrically couple the high voltage well region to the doped body region. The metal shield may provide a flexible connection with between the doped body region and the field plate. The metal shield may provide a physical cover for the area of the LDMOS transistor created using method 200 between the poly gate and the field plate to shield the area from other metal buses having different potential crossing and charges.

Although FIG. 2 discloses a particular number of operations related to method 200, method 200 may be executed with greater or fewer operations than those depicted in FIG. 2. In addition, although FIG. 2 discloses a certain order of operations to be taken with respect to method 200, the operations comprising method 200 may be completed in any suitable order.

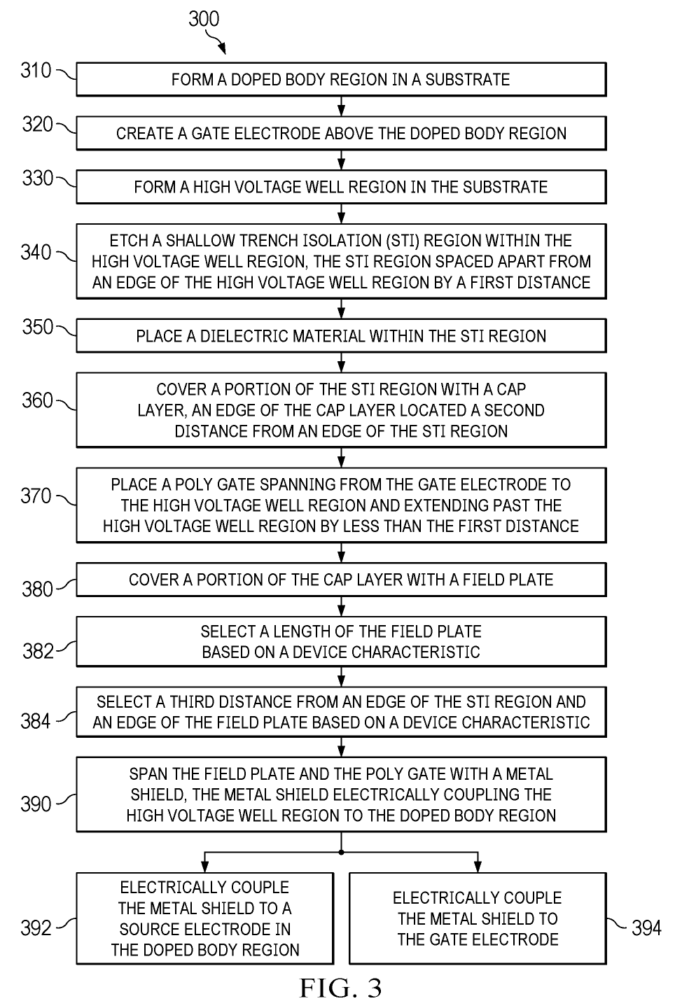

FIG. 3 illustrates a more detailed version of the method shown in FIG. 2 for creating a laterally diffused metal-oxide-semiconductor (LDMOS) transistor that provides immunity from shallow trench isolation (STI) cone defects, according to examples of the present disclosure.

Method 300 may be implemented using any suitable semiconductor manufacturing device designed to perform the functions disclosed herein or any other system operable to implement method 300. Although examples have been described above, other variations and examples may be made from this disclosure without departing from the spirit and scope of these disclosed examples.

Method 300 may begin at block 310 where a doped body region may be formed in a substrate. The substrate may be any suitable substrate, such as, but not limited to, a silicon (Si) substrate, a silicon substrate with Epi, a silicon substrate with a buried layer, or a silicon on insulator (SOI) wafer. In some examples, the substrate may include a deep well. The doped body region may be a p-doped p-body or an n-doped n-body, depending on whether the LDMOS transistor created using method 300 is an N-type LDMOS transistor or a P-type LDMOS transistor. The doped body region may include a source electrode.

At block 320, a gate electrode may be created above the doped body region. The gate electrode may control the flow of current through the LDMOS transistor created using method 300.

At block 330, a high voltage well region may be formed in the substrate. The high voltage well may form the drain region for the LDMOS transistor created using method 300. The high voltage well may be an nwell for an n-type LDMOS transistor or a pwell form a p-type LDMOS transistor. In some examples, the high voltage well may be separated from the doped body region formed in the substrate (at block 310). In other examples, the high voltage well may contact the doped body region.

At block 340, a shallow trench isolation (STI) region may be etched within the high voltage region. The STI region may be spaced apart from an edge of the high voltage well region by a first distance. For example, the first distance may be the distance labeled Lx in FIG. 1. When the shallow trench is etched in the high voltage well, small particles present on the surface of the substrate may block the etching process and cause one or more cone defects. The lateral span of the STI region may be referred to as the drift area.

At block 350, a dielectric material may be placed in the STI region. The dielectric material may be deposited in the STI region to electrically isolate active regions of the LDMOS transistor created using method 300. The dielectric material may be any suitable dielectric material, such as but not limited to, silicon dioxide, silicon oxy-nitride, or silicon carbonitride.

At block 360, a portion of the STI region may be covered with a cap layer. The cap layer may be deposited on the STI region, but not cover the entire STI region. An edge of the cap layer may be located from an edge of the STI region by a second distance. For example, the cap layer may be spaced laterally from an edge of the STI region by the distance labeled La in FIG. 1. The cap layer may be formed of any suitable material, such as, but not limited to, tetraethoxysilane (TEOS), TEOS/silicon nitride (SiN), or SiN/TEOS. The cap layer may reduce the effects of any cone defects present in the STI region. However, because the cap layer cannot cover the entirety the STI region, the cap layer may not provide any protection from cone defects in the portion of the STI region not covered by the cap layer (the distance labeled La in FIG. 1).

At block 370, a poly gate may be placed above the substrate. The poly gate may span from the gate electrode to the high voltage well region. The poly gate may extend past an edge of the high voltage well region by less than the first distance such that the poly gate does not extend past an edge of the STI region or overlap the STI region.

At block 380, a portion of the cap layer may be covered with a field plate. The field plate (e.g., field plate 170 shown in FIG. 1) may extend laterally across the STI region by a distance less than the width of the cap layer.

At block 382, a length of the field plate may be selected based on a device characteristic. Specifically, the distance the field plate is laterally spaced from an edge of the STI region and the length of the field plate may be selected for certain device characteristics, such as, but not limited to, a certain breakdown voltage.

At block 384, a third distance from an edge of the STI region and an edge of the field plate may be selected based on a device characteristic. Specifically, the field plate may be laterally spaced from an edge of the STI region by a distance, labeled Lc in FIG. 1. The distance the field plate may be laterally spaced from an edge of the STI region may be selected for certain device characteristics, such as, but not limited to, a certain breakdown voltage.

At block 390, the field plate and the poly gate may be spanned by a metal shield (e.g., interconnect layer 175 shown in FIG. 1). The metal shield may be electrically couple the high voltage well region to the doped body region. The metal shield may provide a flexible connection with between the doped body region and the field plate. The metal shield may provide a physical cover for the area of the LDMOS transistor created using method 300 between the poly gate and the field plate to shield the area from other metal buses having different potential crossing and charges.

At block 392, the metal shield may be electrically coupled to a source electrode in the doped body region. Specifically, the doped body region may include a contact for a source electrode and the metal shield may be electrically coupled to the contact. The metal shield may electrically couple the field plate with the source electrode.

At block 394, the metal shield may be electrically coupled to the gate electrode (created in the body region at block 320). The metal shield may electrically couple the field plate with the gate electrode.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

Although examples have been described above, other variations and examples may be made from this disclosure without departing from the spirit and scope of these disclosed examples.

1. A laterally-diffused metal-oxide semiconductor (LDMOS) transistor, comprising:
a doped body region formed in a substrate including a source electrode;
a gate electrode above the doped body region;
a high voltage well region formed in the substrate;
a shallow trench isolation (STI) region within the high voltage well region, the STI region spaced apart from an edge of the high voltage well region by a first distance;
a dielectric material within the STI region;
a cap layer covering a portion of the STI region, an edge of the cap layer located a second distance from an edge of the STI region;
a poly gate spanning from the gate electrode to the high voltage well region, the poly gate extending past the high voltage well region by less than the first distance;
a field plate covering a portion of the cap layer; and
a metal shield spanning the field plate and the poly gate and electrically coupling the high voltage well region to the doped body region.

2. The LDMOS transistor of claim 1, wherein:
the doped body region includes a source electrode; and
the metal shield is electrically coupled to the source electrode.

3. The LDMOS transistor of claim 1, wherein the metal shield is electrically coupled to the gate electrode.

4. The LDMOS transistor of claim 1, wherein the doped body region is in contact with the high voltage well region.

5. The LDMOS transistor of claim 1, wherein a length of the field plate is selected based on a device characteristic.

6. The LDMOS transistor of claim 1, wherein a third distance from the edge of the STI region and an edge of the field plate is selected based on a device characteristic.

7. The LDMOS transistor of claim 1, wherein a length of the field plate is less than a length of the cap layer.

8. A method of creating a laterally-diffused metal-oxide semiconductor (LDMOS) transistor, comprising:
forming a doped body region in a substrate;
creating a gate electrode above the doped body region;
forming a high voltage well region in the substrate;
etching a shallow trench isolation (STI) region within the high voltage well region, the STI region spaced apart from an edge of the high voltage well region by a first distance;
placing a dielectric material within the STI region;
covering a portion of the STI region with a cap layer, an edge of the cap layer located a second distance from an edge of the STI region;
placing a poly gate spanning from the gate electrode to the high voltage well region and extending past the high voltage well region by less than the first distance;
covering a portion of the cap layer with a field plate; and
spanning the field plate and the poly gate with a metal shield, the metal shield electrically coupling the high voltage well region to the doped body region.

9. The method of claim 8, comprising electrically coupling the metal shield to a source electrode in the doped body region.

10. The method of claim 8, comprising electrically coupling the metal shield to the gate electrode.

11. The method of claim 8, wherein the doped body region is in contact with the high voltage well region.

12. The method of claim 8, comprising selecting a length of the field plate based on a device characteristic.

13. The method of claim 8, comprising selecting a third distance from the edge of the STI region and an edge of the field plate based on a device characteristic.

14. The method of claim 8, wherein a length of the field plate is less than a length of the cap layer.

15. A laterally-diffused metal-oxide semiconductor (LDMOS) transistor made by a process comprising:
forming a doped body region in a substrate;
creating a gate electrode above the doped body region;
forming a high voltage well region in the substrate;
etching a shallow trench isolation (STI) region within the high voltage well region, the STI region spaced apart from an edge of the high voltage well region by a first distance;
placing a dielectric material within the STI region;
covering a portion of the STI region with a cap layer, an edge of the cap layer located a second distance from an edge of the STI region;
placing a poly gate spanning from the gate electrode to the high voltage well region and extending past the high voltage well region by less than the first distance;
covering a portion of the cap layer with a field plate; and
spanning the field plate and the poly gate with a metal shield, the metal shield electrically coupling the high voltage well region to the doped body region.

16. The LDMOS of claim 15, the process comprising electrically coupling the metal shield to a source electrode in the doped body region.

17. The LDMOS of claim 15, the process comprising electrically coupling the metal shield to the gate electrode.

18. The LDMOS of claim 15, wherein the doped body region is in contact with the high voltage well region.

19. The LDMOS of claim 15, the process comprising selecting a length of the field plate based on a device characteristic.

20. The LDMOS of claim 15, the process comprising selecting a third distance from the edge of the STI region and an edge of the field plate based on a device characteristic.
